(19) United States
(12) Patent Application Publication
(10) Pub. No.: US 2017/0196126 A1
(43) Pub. Date: Jul. 6, 2017

(54) DATA CENTER COOLING SYSTEM

(71) Applicant: HON HAI PRECISION INDUSTRY CO., LTD., New Taipei (TW)

(72) Inventors: TZE-CHERN MAO, New Taipei (TW); CHIH-HUNG CHANG, New Taipei (TW); YEN-CHUN FU, New Taipei (TW); CHAO-KE WEI, New Taipei (TW); YAO-TING CHANG, New Taipei (TW); HUNG-CHOU CHAN, New Taipei (TW)

(21) Appl. No.: 15/055,020

(22) Filed: Feb. 26, 2016

(30) Foreign Application Priority Data
Dec. 30, 2015 (TW) 104144566

(51) Int. Cl. H05K 7/20

(52) U.S. Cl. CPC H05K 7/20836; H05K 7/20736; H05K 7/20745

(57) ABSTRACT

A data center cooling system utilizing natural elements in the environment includes a housing, a chimney, and a data center. The housing defines a cold air channel and a hot air channel separated by at least one separating piece. The chimney is mounted on the housing and aligned to the hot air channel. The data center is located in the housing. The data center includes an air inlet side and an air outlet side. The air inlet side is located in the cold air channel. The air outlet side is located in the hot air channel. Air from the cold air channel flows in the data center from the air inlet side to absorb heat of the data center, flows out of the data center into the hot air channel via the air outlet side, and is exhausted out of the housing via the chimney.

### CROSS-REFERENCE TO RELATED APPLICATIONS

This application claims priority to Taiwanese Patent Application No. 104144566 filed on Dec. 30, 2015, the contents of which are incorporated by reference herein.

### FIELD

The subject matter herein relates to a data center cooling system.

### BACKGROUND

Container data centers generate a lot of heat during operation. The container data center is generally contained in a housing. A number of air conditioning devices can be arranged in the housing to lower the temperature of the container data enter.

### BRIEF DESCRIPTION OF THE DRAWINGS

Implementations of the present technology will now be described, by way of example only, with reference to the attached figures.

FIG. 1 is sketch view of a data center cooling system.

FIG. 2 is a sketch view of a housing of the data center cooling system of FIG. 1.

FIG. 3 is a front view of the housing of FIG. 2.

FIG. 4 is an isometric, partial view of the housing of FIG. 2.

FIG. 5 is another isometric, partial view of the housing of FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series and the like.

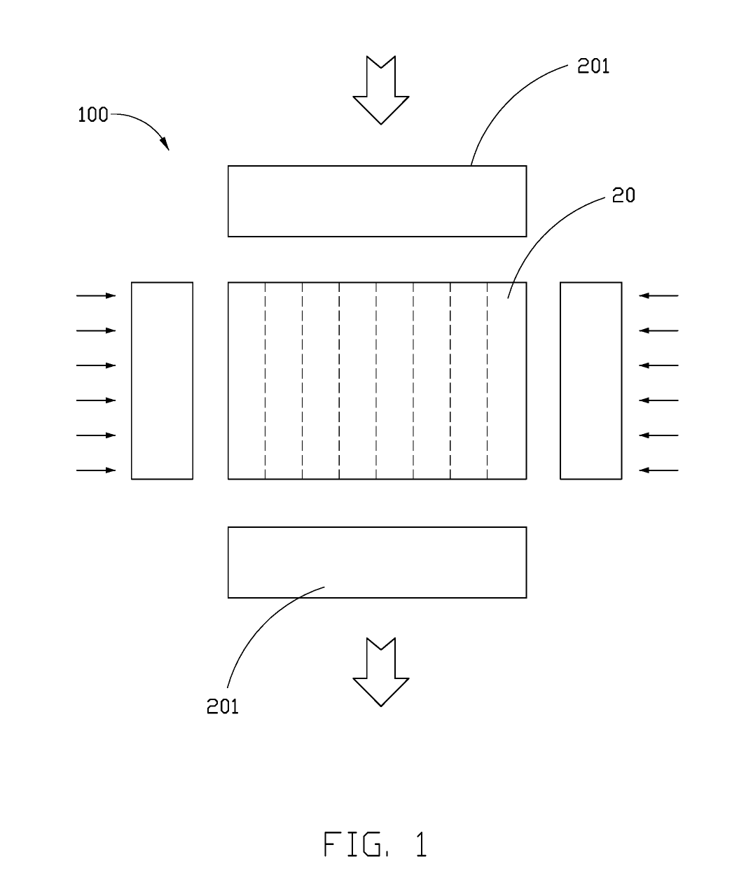

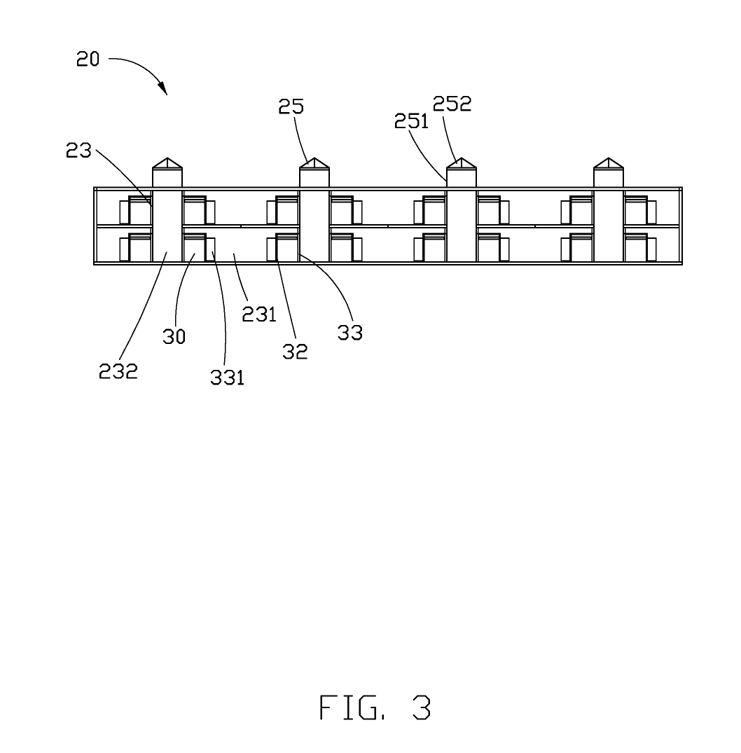

FIGS. 1 to 3 illustrates that a data center cooling system 100 includes a housing 20, a plurality of water pools 201 located around the housing 20, and a plurality of growing plants 40 coated on a outer side of the housing 20. The housing 20 receives a plurality of data centers 30 therein. The data cooling system 100 is used to cool the data centers 30. In at least one embodiment, the data center 30 is a container data center.

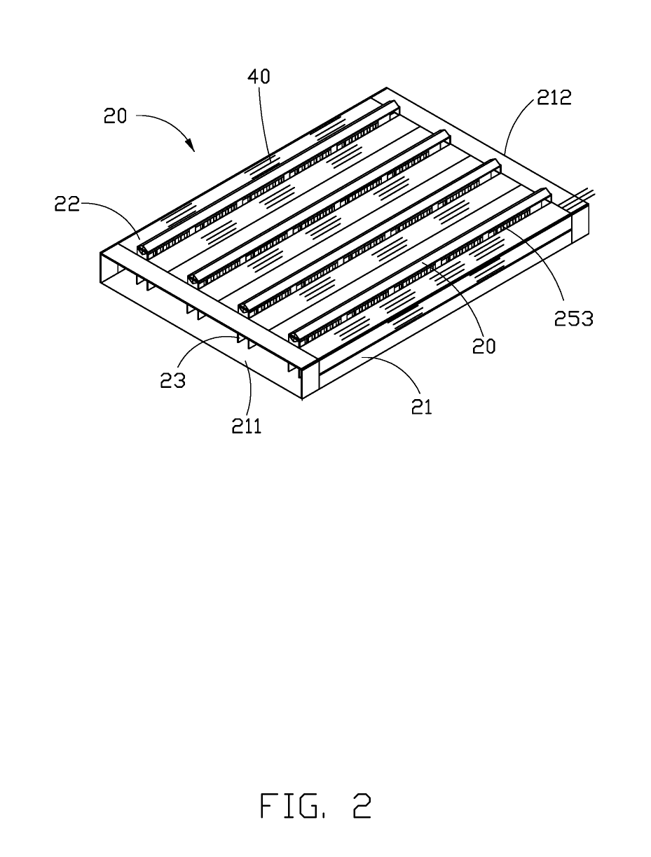

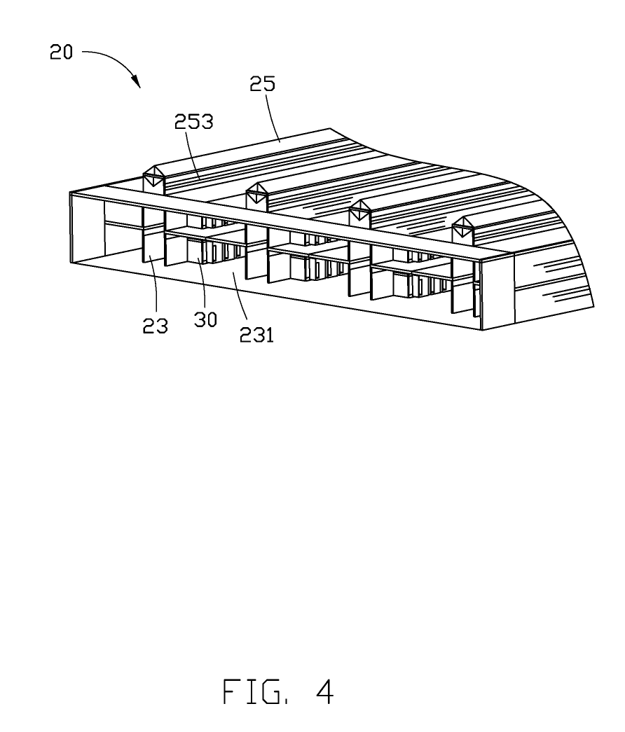

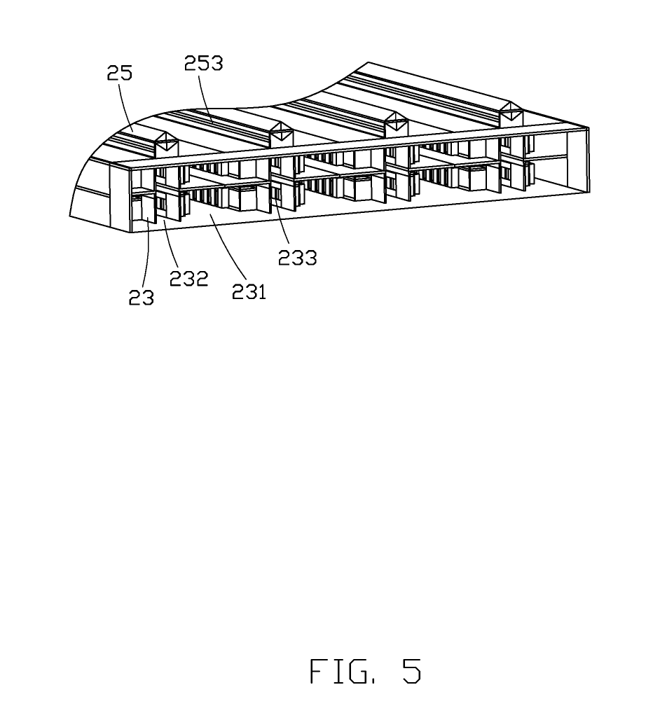

Referring to FIGS. 2 to 5, the housing 20 includes a pair of side walls 21 and a top wall 22. The top wall 22 is connected between top edges of the pair of side walls 21. Front edges of the pair of side walls 21 define an first opening 211. Rear edges of the pair of side walls 21 define an second opening 212. An inner room of the housing 20 is divided by several pairs of separating pieces 23 to form a plurality of air channels. The air channel located between each pair of separating pieces 23 is a hot air channel 232. The air channel located between two adjacent pairs of separating pieces 23 or located between the side wall 21 and one separating piece 23 is a cold air channel 231. The hot air channel 232 is separated from the cold air channel 232 by one separating piece 23. The separating piece 23 defines a plurality of openings 233. Each opening 233 is aligned to an air outlet side 33 of the data center 30. An air inlet side 32 of the data center 30 is located in the cold air channel 231. A plurality of air cooling apparatuses 31 (such as fans, air-condition, and so on.) is mounted on the air inlet side 32 of the data center 30 to guide air into the data center 30. In at least one embodiment, the housing 20 has two floors. Each floor can receive the data centers 30. In other embodiment, the housing 20 can have three or more floors.

A top edge of the separating piece 23 is connected to a bottom side of the top wall 22. The top wall 22 defines a plurality of openings (not shown) aligned to the plurality of hot air channels 232. A plurality of chimneys 25 is mounted on the top wall 22 and aligned to the plurality of hot air channels 232. The chimney 25 includes two side portions 251 and a top portion 252. The side portion 251 defines a plurality of air vents 253.

The plurality of growing plants 40 is coated on an outer side of the housing 20. In at least one embodiment, the housing 20 can be positioned at hilly area. The housing 20 can be made of soil. Thus, heat transferred to the inside of the housing 20 can be reduced.

When the data cooling system 100 works, air flows in the cold air channel 231 via a top portion of the pools 201 and the first opening 211. Evaporation of water of the pools 201 cools the air flowing in the cold air channel 231. The air cooling apparatuses 31 guide air flow in the data center 30. The air absorbs heat of the data center 30 and flows into the hot air channel 232 via the opening 233. The air then flows upwardly to the chimney 25 under Stack effect and is exhausted out of housing 20 via the air vents 253 of the chimney 25.

In the above embodiment, doors can be mounted on opposite sides of the hot air channel 232. The doors can be opened to dissipate heat when the chimney 25 is blocked.

Further, the housing 20 can be placed in a position exposed to wind, such as pass or a position located between two high buildings.

When a direction of the airflow changes, cold air also can flow in the cold air channel 231 via the second opening 212.

The embodiments shown and described above are only examples. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A data center cooling system comprising:
a housing defining a cold air channel and a hot air channel separated by at least one separating piece;
a chimney mounted on the housing and aligned to the hot air channel, so that air in the hot air channel can pass to an inside of the chimney;
a data center located in the housing, the data center comprising an air inlet side and an air outlet side, the air inlet side located in the cold air channel, the air outlet side located in the hot air channel,
wherein air of the cold air channel flows into the data center from the air inlet side, absorbs heat from the data center, flows out of the data center into the hot air channel via the air outlet side, and is exhausted out of the hosing via the chimney.

2. The data center cooling system of claim 1, wherein air flows upwardly from the hot air channel to the chimney under Stack effect.

3. The data center cooling system of claim 1, wherein the separating piece defines an opening which is aligned to the air outlet side of the data center.

4. The data center cooling system of claim 1, wherein the at least one separating piece comprises a pair of separating pieces, and the hot air channel is defined between the pair of separating pieces.

5. The data center cooling system of claim 1, wherein the housing defines an first opening which is communicated to the cold air channel.

6. The data center cooling system of claim 5, wherein a pool is located behind the first opening.

7. The data center cooling system of claim 1, wherein a plurality of growing plants is coated on an outer side of the housing.

8. The data center cooling system of claim 1, wherein the housing comprises a plurality of floors.

9. The data center cooling system of claim 1, wherein the housing is located in a pass or between two high buildings.

10. A data center cooling system, comprising:
a housing comprising a separated to separate a cold air channel from a hot air channel;
a chimney located above the hot air channel;
a data center comprising an air inlet side and an air outlet side, the air inlet side located in the cold air channel, the air outlet side located in the hot air channel;
wherein air of the cold air channel flows in the data center from the air inlet side to absorb heat of the data center, flows out of the data center into the hot air channel via the air outlet side, and flows upwardly from the hot air channel to the chimney under Stack effect.

11. The data center cooling system of claim 10, wherein the separating piece defines an opening which is aligned to the air outlet side of the data center.

12. The data center cooling system of claim 10, wherein the at least one separating piece comprises a pair of separating pieces, and the hot air channel is defined between the pair of separating pieces.

13. The data center cooling system of claim 10, wherein the housing defines an first opening which is communicated to the cold air channel.

14. The data center cooling system of claim 13, wherein a pool is located behind the first opening.

15. The data center cooling system of claim 10, wherein a plurality of growing plants is coated on an outer side of the housing.

16. The data center cooling system of claim 10, wherein the housing comprises a plurality of floors.

17. The data center cooling system of claim 10, wherein the housing is located in a pass or between two high buildings.
